(19) United States
(12) Patent Application Publication
(10) Pub. No.: US 2022/0246594 A1
(43) Pub. Date: Aug. 4, 2022

(54) LIGHT EMITTER BOARD AND DISPLAY DEVICE

(71) Applicant: KYOCERA Corporation, Kyoto-shi, Kyoto (JP)

(72) Inventors: Takashi SHIMIZU, Kusatsu-shi, Shiga (JP); Hiroaki ITO, Ritto-shi, Shiga (JP)

(21) Appl. No.: 17/617,184

(22) PCT Filed: May 26, 2020
(86) PCT No.: PCT/JP2020/020761

§ 371 Date: Dec. 7, 2021

(30) Foreign Application Priority Data
Jun. 11, 2019 (JP) 2019-108815

(51) Int. Cl. H01L 25/16; H01L 33/58; H01L 33/62; H01L 27/12

(52) U.S. Cl. CPC H01L 25/167; H01L 33/58; H01L 24/05; H01L 27/1248; H01L 33/62

(57) ABSTRACT

A light emitter board includes a substrate such as a glass substrate, a resin insulating layer as a first insulating layer on the substrate, a light shield layer as a second insulating layer on the resin insulating layer, an opening portion in the light shield layer, a mount located on a part of the resin insulating layer exposed in the opening portion and receiving a light emitter, and the light emitter on the mount. The mount includes a protrusion on the part of the resin insulating layer. The light emitter on the mount has an upper surface located above an upper surface of the light shield layer.

### FIELD

The present disclosure relates to a light emitter board on which light emitters such as light-emitting diodes (LEDs) are mountable and a display device including the light emitter board.

### BACKGROUND

A known self-luminous light emitter board without a backlight device includes multiple light emitters such as LEDs, and a known display device includes the light emitter board (refer to, for example, Patent Literatures 1 and 2).

### CITATION LIST

### Patent Literature

Patent Literature 1: Japanese Unexamined Patent Application Publication No. 2019-028284
Patent Literature 2: Japanese Unexamined Patent Application Publication No. 2005-317950

### BRIEF SUMMARY

A light emitter board according to an aspect of the present disclosure includes a substrate, a first insulating layer on the substrate, a second insulating layer on the first insulating layer, an opening portion in the second insulating layer, at least one mount located on a part of the first insulating layer exposed in the opening portion and receiving at least one light emitter, and the at least one light emitter on the at least one mount. The at least one mount includes a protrusion on the part of the first insulating layer. The at least one light emitter has an upper surface located above an upper surface of the second insulating layer.

A display device according to another aspect of the present disclosure includes the light emitter board with the above structure. The substrate has a first surface receiving the at least one light emitter, a second surface opposite to the first surface, and side surfaces. The light emitter board includes side wiring on the side surfaces and a driver on the second surface. The at least one light emitter is connected to the driver with the side wiring.

### Advantageous Effects

The light emitter board according to the above aspects of the present disclosure reduces the likelihood of side emission light from the light emitters being absorbed and partially reflected by the second insulating layer. This reduces the likelihood that the luminance of each light emitter decreases and the contrast in a displayed image decreases. The light emitters each having the upper surface located above the upper surface of the second insulating layer are more reliably pressed onto the mounts from above for bonding. This structure reduces the likelihood that the bonding strength of the light emitters to the mounts decreases.

The display device according to the above aspects of the present disclosure reduces the likelihood that the luminance of the light emitters decreases and the contrast in a displayed image decreases. When being mounted on the mounts, the light emitters are more reliably pressed onto the mounts from above. This structure reduces the likelihood that the bonding strength of the light emitters to the mounts decreases. The display device thus has a higher yield in mounting the light emitters onto the light emitter board and has a long service life.

### BRIEF DESCRIPTION OF DRAWINGS

The objects, features, and advantages of the present invention will become more apparent from the following detailed description and the drawings.

FIG. 1 is a circuit diagram of multiple light emitters and emission controllers that control the light emitters included in a light emitter board according to an embodiment of the present disclosure.

FIG. 2 is a plan view of the multiple light emitters in FIG. 1 and mounts on which the light emitters are mounted in the embodiment of the present disclosure.

FIG. 3 is a cross-sectional view taken along line C1-C2 in FIG. 1.

FIG. 4 is a cross-sectional view of a light emitter board with the structure in FIG. 3 including a light shield.

FIG. 5 is a block circuit diagram of a display device with the structure that forms the basis of a display device according to an embodiment of the present disclosure.

FIG. 6 is a bottom view of the display device in FIG. 5.

FIG. 7 is a cross-sectional view of the display device taken along line A1-A2 in FIG. 5.

FIG. 8 is a circuit diagram of a single light emitter and an emission controller connected to the light emitter in the display device in FIG. 5.

FIG. 9 is a cross-sectional view taken along line B1-B2 in FIG. 8.

### DETAILED DESCRIPTION

One or more embodiments of the present invention will now be described in detail with reference to the drawings.

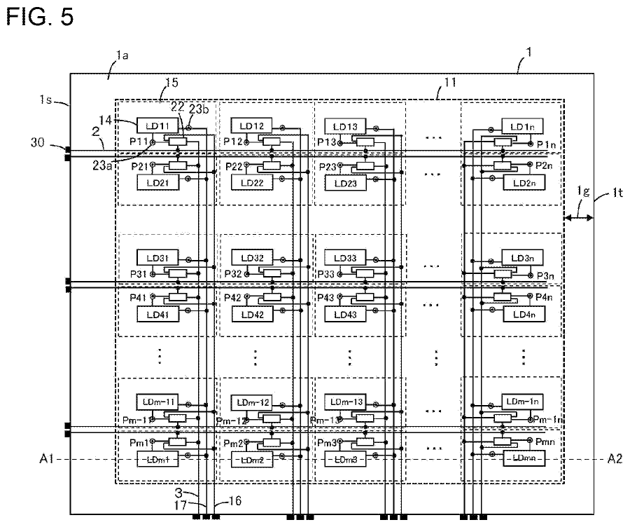

The structure that forms the basis of a light emitter board and a display device including the light emitter board according to one or more embodiments of the present disclosure will be described first with reference to FIGS. 5 to 9.

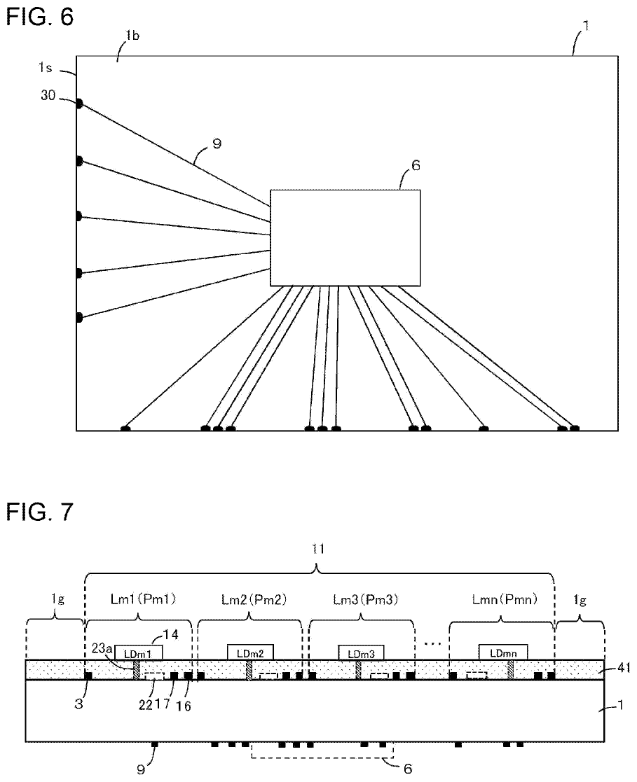

FIG. 5 is a block circuit diagram of a display device with the structure that forms the basis of the display device according to one or more embodiments of the present disclosure. FIG. 6 is a bottom view of the display device in FIG. 5. FIG. 7 is a cross-sectional view taken along line A1-A2 in FIG. 5. The display device includes a substrate 1 such as a glass substrate, scanning signal lines 2 extending in a predetermined direction (e.g., a row direction) on the substrate 1, emission control signal lines 3 crossing the scanning signal lines 2 and extending in a direction (e.g., a column direction) crossing the predetermined direction, a display 11 including multiple pixel units (Pmn) defined by the scanning signal lines 2 and the emission control signal lines 3, and multiple emissive areas (Lmn) on an insulating layer covering the display 11.

The scanning signal lines 2 and the emission control signal lines 3 are connected to back wiring 9 on the back surface of the substrate 1 with side wiring 30 on side surfaces of the substrate 1. The back wiring 9 is connected to a driving element 6 such as an integrated circuit (IC) and a large-scale integration (LSI) circuit mounted on the back surface of the substrate 1. In other words, the display in the display device is driven and controlled by the driving element 6 on the back surface of the substrate 1. The driving element 6 is mounted on the back surface of the substrate 1 by, for example, chip on glass (COG). The back surface of the substrate 1 may receive a flexible printed circuit (FPC) for inputting and outputting, for example, driving signals and control signals to and from the driving element 6 with lead lines. The side wiring 30 may be replaced by feedthrough conductors such as through-holes.

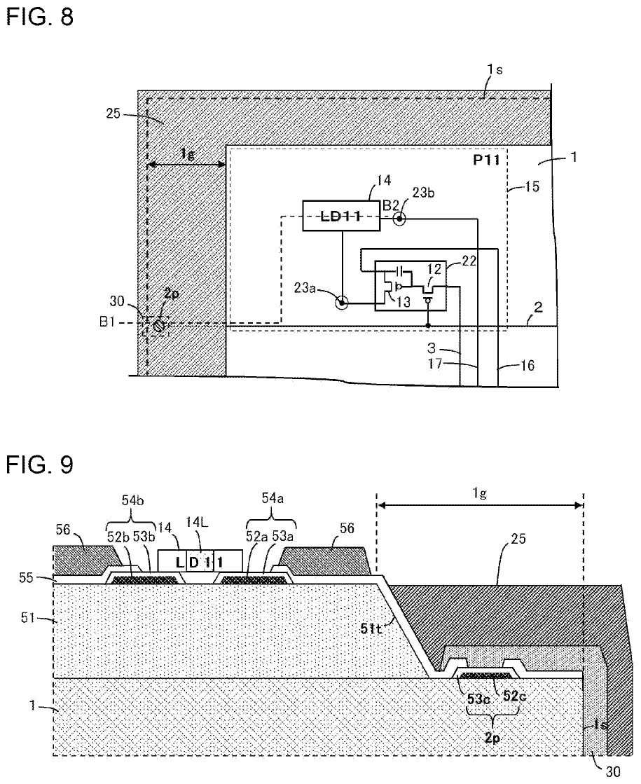

Each pixel unit 15 (Pmn) includes an emission controller 22 to control, for example, the emission or non-emission state and the light intensity of a light emitter 14 (LDmn) in the emissive area (Lmn). The emission controller 22 includes a thin-film transistor (TFT) 12 (shown in FIG. 8) as a switch for inputting an emission signal into the light emitter 14 and a TFT 13 (shown in FIG. 8) as a driving element for driving the light emitter 14 with a current using an electric potential difference (emission signal) between a positive voltage (an anode voltage of about 3 to 5 V) and a negative voltage (a cathode voltage of about −3 to 0 V) corresponding to the level (voltage) of an emission control signal (a signal transmitted through the emission control signal line 3). A connection line connecting a gate electrode and a source electrode of the TFT 13 receives a capacitor, which retains the voltage of the emission control signal input into the gate electrode of the TFT 13 until the subsequent rewriting is performed (for a period of one frame).

The light emitter 14 is electrically connected to the emission controller 22, a positive voltage input line 16, and a negative voltage input line 17 with feedthrough conductors 23a and 23b such as through-holes formed through an insulating layer 41 (shown in FIG. 7) covering the display 11. In other words, the positive electrode of the light emitter 14 is connected to the positive voltage input line 16 with the feedthrough conductor 23a and the emission controller 22, and the negative electrode of the light emitter 14 is connected to the negative voltage input line 17 with the feedthrough conductor 23b.

The display device also includes a frame 1g between the display 11 and an edge 1t of the substrate 1 (shown in FIG. 5) as viewed in plan. The frame 1g, which does not contribute to display, may receive an emission control signal line drive circuit, a scanning signal line drive circuit, and other components. The width of the frame 1g is to be minimized. Multiple substrates 1 are cut out of a single mother substrate. For the emission controller 22 to avoid being affected by the cutting lines, as shown in the block circuit diagram of FIG. 5, a known structure includes the emission controller 22 inward from the light emitter 14 in the pixel unit 15 at the outermost periphery of the substrate 1 as viewed in plan.

FIG. 8 is an enlarged partial plan view of the pixel unit 15 (P11) at the outermost periphery of the display device in FIG. 5. FIG. 9 is a cross-sectional view taken along line B1-B2 in FIG. 8. As shown in these figures, the display device includes a light shield 25 over the frame 1g, which surrounds the display 11 and does not contribute to display, to cause the frame 1g to be inconspicuous. The light shield 25 includes, for example, a black matrix.

As shown in FIG. 9, a resin insulating layer 51 formed from, for example, an acrylic resin is located on the substrate 1, which may be a glass substrate. The light emitter 14 is mounted on the resin insulating layer 51.

The light emitter 14 is electrically connected to a positive electrode 54a and a negative electrode 54b on the resin insulating layer 51 with a conductive connector, such as an anisotropic conductive film (ACF) and solder, and is mounted on the resin insulating layer 51. The positive electrode 54a includes an electrode layer 52a including, for example, Mo/Al/Mo layers (a stack of a Mo layer, an Al layer, and a Mo layer in this order), and a transparent electrode 53a formed from, for example, indium tin oxide (ITO) to cover the electrode layer 52a. The negative electrode 54b has the same structure and includes an electrode layer 52b including, for example, Mo/Al/Mo layers and a transparent electrode 53b formed from, for example, ITO to cover the electrode layer 52b. An electrode pad 2p is located nearer the edge 1t of the substrate 1 than the positive electrode 54a and the negative electrode 54b on the resin insulating layer 51. The electrode pad 2p includes an electrode layer 52c and a transparent electrode 53c formed from, for example, ITO to cover the electrode layer 52c. The electrode pad 2p is electrically connected to the positive electrode 54a or the negative electrode 54b, and serves as a relay electrode to be electrically connected to the back wiring 9 with the side wiring 30.

An insulating layer 55 formed from, for example, silicon oxide (SiO₂) or silicon nitride (SiN_{X}) is located to cover the resin insulating layer 51, portions of the transparent electrodes 53a and 53b (portions on which the light emitter 14 is not mounted), and the periphery of the transparent electrode 53c. A light shield layer 56, which may include a black matrix, is located on the insulating layer 55 excluding a mount on which the light emitter 14 is mounted and a portion on which the light shield 25 is arranged. The display device includes the light shield layer 56 to cause the portions other than the light emitter 14 to have a dark background color such as black as viewed in plan.

The side wiring 30, which electrically connects the electrode pad 2p and the back wiring 9, extends from a portion of the insulating layer 55 covering the electrode pad 2p as viewed in plan to the back surface of the substrate 1 through the side surface of the substrate 1. The side wiring 30 is prepared by applying a conductive paste including conductive particles, such as silver, and firing the paste. The light shield 25 covers the electrode pad 2p and the side wiring 30. The light emitter 14 includes the positive electrode connected to the positive electrode 54a with a conductive connector, such as an ACF or solder, and the negative electrode connected to the negative electrode 54b with a conductive connector, such as an ACF or solder. The light emitter 14 is thus mounted on the substrate 1.

In the display device shown in FIGS. 5 to 9, light emitted from a light emitting unit 14L in the light emitter 14 includes light components (side emission light) emitted from the side surfaces of the light emitter 14. The side emission light may be absorbed and partially reflected by the light shield layer 56. The side emission light may also be absorbed and partially reflected by the light shield 25. In such cases, the absorbed side emission light easily decreases the luminance of the light emitter 14, and the partially reflected side emission light easily decreases the contrast in a displayed image.

Manufacturing a display device typically uses, for example, a mounting technique using a plate jig having recesses or through-holes accommodating corresponding many (about 10,000 to several million) light emitters 14, which is then turned upside down over the substrate 1 with the light emitters 14 being placed onto the respective mounts on the substrate 1, or a transfer method using an adhesive sheet on which many light emitters 14 are arranged, which is then turned upside down over the substrate 1 with the light emitters 14 being placed onto the respective mounts on the substrate 1. With these methods, the light emitters 14 mounted on the respective mounts on the substrate 1 may be pressed onto the mounts from above with the above plate jig or with a pressing plate for more reliable bonding of the light emitters 14 with the mounts. In this case, all the light emitters 14 having the upper surfaces at the same level as or below the upper surface of the light shield layer 56 and the light shield 25 are difficult to press, and thus some light emitters 14 may have lower bonding strength.

Other known examples include a method for assembling an LED assembly including attaching a flip-chip LED on a sub-mount to a plastic cylinder having an embedded lead frame, and then mounting the structure on a printed wiring board, and an LED assembly assembled with the method. However, these known techniques do not include any structure that can solve the above issue.

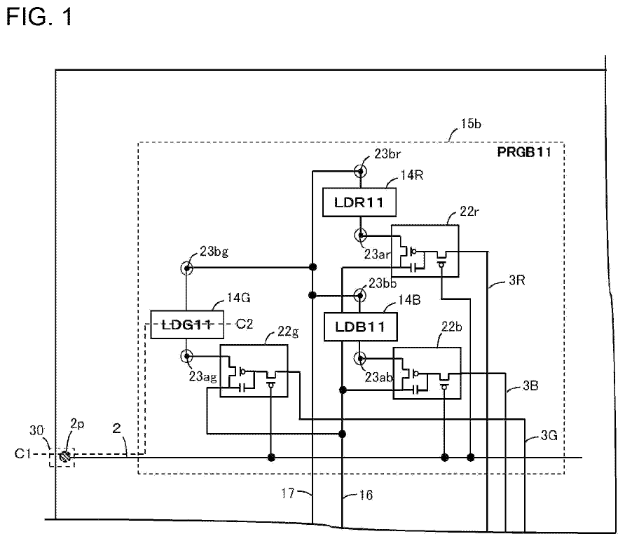

A light emitter board and a display device according to one or more embodiments of the present disclosure will now be described with reference to the drawings. Each figure referred to below shows main components of the light emitter board and the display device according to one or more embodiments of the present disclosure. The light emitter board and the display device according to one or more embodiments of the present disclosure may thus include known components not shown in the figures, such as circuit boards, wiring conductors, control ICs, and LSI circuits. In FIGS. 1 to 4 showing the light emitter board and the display device according to one or more embodiments of the present disclosure, the same components as in FIGS. 5 to 9 are given the same reference numerals and will not be described in detail.

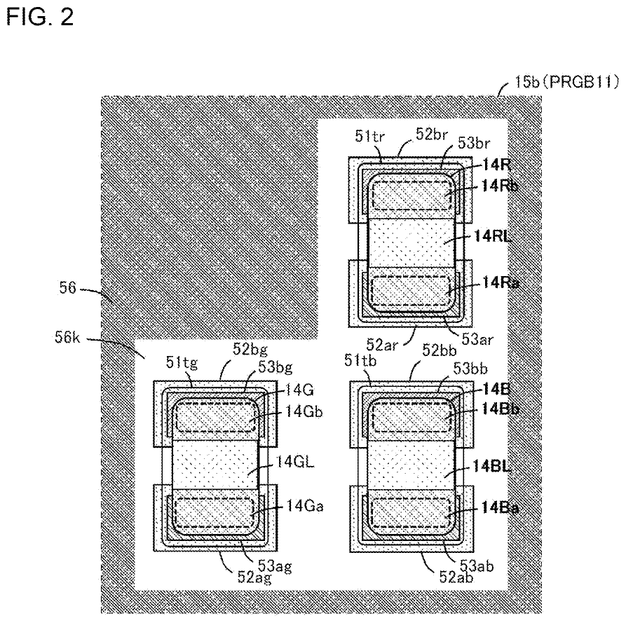

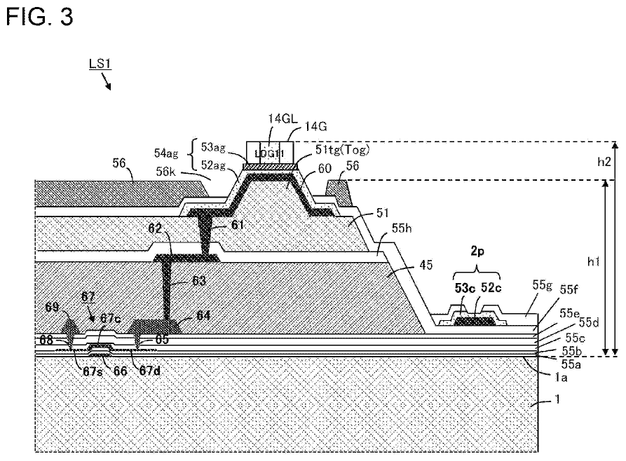

FIGS. 1 to 4 are diagrams of the light emitter board according to one or more embodiments of the present disclosure. As shown in FIGS. 1 to 3, a light emitter board LS1 according to the present embodiment includes a substrate 1 such as a glass substrate, a resin insulating layer 51 on the substrate 1 as a first insulating layer, a light shield layer 56 as a second insulating layer on the resin insulating layer 51, an opening portion 56k (shown in FIGS. 2 and 3) in the light shield layer 56, a mount 51tg for receiving a light emitter 14G (shown in FIG. 3) on a part of the resin insulating layer 51 exposed in the opening portion 56k, and the light emitter 14G on the mount 51tg. In the light emitter board LS1, the mount 51tg includes a protrusion Tog (shown in FIG. 3) on a part of the resin insulating layer 51, and the light emitter 14G mounted on the mount 51tg has its upper surface located above the upper surface of the light shield layer 56. More specifically, a height h2 (shown in FIG. 3) from a first surface 1a of the substrate 1 on which the light emitter 14G is mounted to the upper surface of the light emitter 14G is greater than a height h1 (shown in FIG. 3) from the first surface 1a to the upper surface of the light shield layer 56.

The above structure produces the advantageous effects described below. The structure reduces the likelihood of side emission light from the light emitter 14G being absorbed and partially reflected by the light shield layer 56. This reduces the likelihood that the luminance of the light emitter 14G decreases and the contrast in a displayed image decreases. The light emitter 14G has its upper surface located above the upper surface of the light shield layer 56. Thus, the light emitter 14G is more reliably pressed onto the mount 51tg from above when pressed onto the mount 51tg from above for bonding. This reduces the likelihood that the bonding strength of the light emitter 14G to the mount 51tg decreases.

In the light emitter board according to one or more embodiments of the present disclosure, a single opening portion 56k may receive one or more mounts 51tg each receiving multiple light emitters 14G including a light emitter that emits red light, a light emitter that emits green light, and a light emitter that emits blue light.

A single opening portion 56k may receive multiple mounts 51tg each receiving one light emitter 14G. The light emitters 14G may have different emission colors. For example, a single opening portion 56k may include a first mount receiving a light emitter that emits red light, a second mount receiving a light emitter that emits green light, and a third mount receiving a light emitter that emits blue light. In this case, the light emitter that emits red light, the light emitter that emits green light, and the light emitter that emits blue light may have different heights. The upper surfaces of the respective light emitters can be at the same height from the first surface 1a of the substrate 1 by adjusting the heights of the first mount, the second mount, and the third mount. This improves the yield in mounting the light emitters.

As shown in FIG. 3, the light emitter board LS1 includes insulating layers 55a to 55g sequentially stacked on one another on the first surface 1a of the substrate 1. The insulating layers 55a to 55g are formed from, for example, SiO₂ and Si₃N₄. A TFT 67 is located between the first surface 1a of the substrate 1 and the insulating layers 55a to 55c. A semiconductor layer 67c included in the TFT 67 includes a source 67s connected to a source electrode 69 through a through-hole 68, and a drain 67d connected to a drain electrode 64 through a through-hole 65. The drain electrode 64 is connected to a lower electrode layer 60 through a through-hole 63, interlayer wiring 62, and a through-hole 61. The through-hole 63 is in a lower resin insulating layer 45 stacked on the insulating layer 55e. The lower electrode layer 60 is formed from the same material as an electrode layer 52ag.

The protrusion Tog on a part of the resin insulating layer 51 included in the mount 51tg for receiving the light emitter 14G includes the lower electrode layer 60, the electrode layer 52ag, and a transparent electrode 53ag. The protrusion Tog may be a part of the resin insulating layer 51 processed, or for example, exposed and removed. The protrusion Tog may be, for example, a resin piece separate from but bonded to the resin insulating layer 51 with an adhesive or in any other manner.

Although the protrusion Tog includes the lower electrode layer 60, the electrode layer 52ag, and the transparent electrode 53ag, the protrusion Tog may include a transparent electrode layer as the electrode layer 52ag and eliminate the transparent electrode 53ag.

The substrate 1 included in the light emitter board LS1 may be a translucent substrate such as a glass substrate or a plastic substrate, or a non-translucent substrate such as a ceramic substrate, a non-translucent plastic substrate, or a metal substrate. The substrate 1 may further be a composite substrate including a laminate of a glass substrate and a plastic substrate, a laminate of a glass substrate and a ceramic substrate, a laminate of a glass substrate and a metal substrate, or a laminate of at least any two of the above substrates formed from different materials. The substrate 1 including an electrically insulating substrate, such as a glass substrate, a plastic substrate, or a ceramic substrate, facilitates formation of wiring. The substrate 1 may be rectangular, circular, oval, trapezoidal, or in any other shape as viewed in plan.

As shown in FIG. 2, the light emitter 14G emits green light, a light emitter 14R emits red light, and a light emitter 14B emits blue light. The light emitters 14G, 14R, and 14B are collectively referred to as the light emitters 14. The light emitters 14 may be any self-luminous light emitters such as micro-LEDs, monolithic LEDs, organic electroluminescence (EL) elements, inorganic EL elements, and semiconductor laser elements.

The light emitters 14 used in the light emitter board LS1 according to the present embodiment may be micro-LEDs, which are backlight-free and self-luminous, and have high emission efficiency and a long service life. In the example below, the light emitters 14 are micro-LEDs 14.

As shown in FIG. 2, a micro-LED 14G is mounted horizontally and includes a positive electrode 14Ga and a negative electrode 14Gb on its lower surface (surface adjacent to the substrate 1) with a space from each other as viewed in plan. A light emitting unit 14GL is in the middle between the positive electrode 14Ga and the negative electrode 14Gb as viewed in plan. The positive electrode 14Ga is connected to a positive electrode pad 54ag on the substrate 1 with a conductive connector such as solder or an ACF. The negative electrode 14Gb is connected to a negative electrode pad 54bg on the substrate 1 with the conductive connector.

Similarly, a micro-LED 14R is mounted horizontally and includes a positive electrode 14Ra and a negative electrode 14Rb on its lower surface with a space from each other as viewed in plan. A light emitting unit 14RL is in the middle between the positive electrode 14Ra and the negative electrode 14Rb as viewed in plan. The positive electrode 14Ra is connected to a positive electrode pad 54ar on the substrate 1 with the conductive connector. The negative electrode 14Rb is connected to a negative electrode pad 54br on the substrate 1 with the conductive connector.

Similarly, a micro-LED 14B is mounted horizontally and includes a positive electrode 14Ba and a negative electrode 14Bb on its lower surface with a space from each other as viewed in plan. A light emitting unit 14BL is in the middle between the positive electrode 14Ba and the negative electrode 14Bb as viewed in plan. The positive electrode 14Ba is connected to a positive electrode pad 54ab on the substrate 1 with the conductive connector. The negative electrode 14Bb is connected to a negative electrode pad 54bb on the substrate 1 with the conductive connector.

In the above embodiment, the micro-LEDs include the positive electrode and the negative electrode on their lower surfaces and are mounted horizontally. In some embodiments, the micro-LEDs may include one of the positive electrode and the negative electrode on their lower surfaces and the other electrode on their upper surfaces, and may be mounted vertically.

In some embodiments, the micro-LEDs 14 may be mounted vertically on (perpendicularly to) the first surface 1a of the substrate 1. In this case, the mounted micro-LEDs 14 include, for example, a positive electrode, an emissive layer, and a negative electrode stacked in this order from the first surface 1a.

Each micro-LED 14 rectangular as viewed in plan may have, but is not limited to, each side with a length of about 1 to 100 μm inclusive, or more specifically about 3 to 10 μm inclusive.

As shown in FIGS. 1 and 2, one pixel unit (PRGB11) 15b may include micro-LEDs 14R, 14G, and 14B having different emission colors. For example, the micro-LED 14R may emit red, orange, red-orange, red-violet, or violet light. The micro-LED 14G may emit green or yellow-green light. The micro-LED 14B may emit blue light. The light emitter board according to the present embodiment thus facilitates fabrication of a color display device. A single pixel unit 15b including three or more micro-LEDs 14 may have two or more micro-LEDs 14 having the same emission color.

The positive electrode 14Ra (14Ga, 14Ba) and the negative electrode 14Rb (14Gb, 14Bb) of the micro-LED 14R (14G, 14B) are conductor layers including, for example, tantalum (Ta), tungsten (W), titanium (Ti), molybdenum (Mo), aluminum (Al), chromium (Cr), silver (Ag), or copper (Cu). The positive electrode 14Ra (14Ga, 14Ba) and the negative electrode 14Rb (14Gb, 14Bb) may be metal layers including Mo/Al/Mo layers (a stack of a Mo layer, an Al layer, and a Mo layer in this order) or metal layer(s) including an Al layer, Al/Ti layers, Ti/Al/Ti layers, a Mo layer, Mo/Al/Mo layers, Ti/Al/Mo layers, Mo/Al/Ti layers, a Cu layer, a Cr layer, a Ni layer, or a Ag layer.

An electrode layer 52ar (52ag, 52ab) in the positive electrode pad 54ar (54ag, 54ab) and an electrode layer 52br (52bg, 52bb) in the negative electrode pad 54br (54bg, 54bb) may have the same structure as the positive electrode 14Ra (14Ga, 14Ba) and the negative electrode 14Rb (14Gb, 14Bb).

A transparent electrode 53ar (53ag, 53ab) on the electrode layer 52ar (52ag, 52ab) and a transparent electrode 53br (53bg, 53bb) on the electrode layer 52br (52bg, 52bb) are transparent conductive layers including a transparent, conductive material such as ITO, indium zinc oxide (IZO), silicon oxide-doped indium tin oxide (ITSO), zinc oxide (ZnO), and silicon (Si) containing phosphorus and boron.

In the light emitter board LS1 according to the present embodiment, as shown in FIG. 3, the micro-LED 14G mounted on the mount 51tg may have its overall side surface located above the upper surface of the light shield layer 56. In other words, the top surface of the protrusion Tog is a mount surface receiving the micro-LED 14G, and the mount surface may be located above the upper surface of the light shield layer 56. This structure further reduces the likelihood of side emission light from the micro-LED 14G being absorbed and partially reflected by the light shield layer 56.

Additionally, the micro-LED 14G is more reliably pressed onto the mount 51tg from above for bonding. In this case, the lower end of the side surface of the micro-LED 14G may be located above the upper surface of the light shield layer 56 by 0 to 100 μm inclusive. When the value is less than 0 μm, side emission light from the micro-LED 14G is more likely to be absorbed and partially reflected by the light shield layer 56. When the value is greater than 100 μm, the light emitter board LS1 is more likely to have an excessively large thickness.

The light emitter board LS1 according to the present embodiment may have the light shield layer 56 in a dark color. This further reduces the likelihood of side emission light from the micro-LED 14G being partially reflected by the light shield layer 56. This reduces the likelihood that the contrast in a displayed image decreases. The dark-colored light shield layer 56 may have a color that efficiently absorbs and blocks visible light, such as black, blackish brown, dark brown, dark blue, or dark purple. The dark-colored light shield layer 56 may include a transparent resin layer containing, for example, dark-colored pigments, dyes, ceramic particles, metal particles, alloy particles, or resin particles.

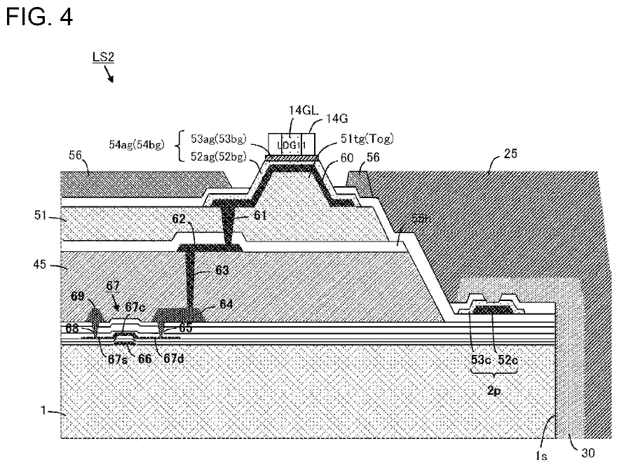

As shown in FIG. 4, a light emitter board LS2 according to the present embodiment includes a dark-colored light shield 25 covering a side surface is of the substrate 1. The micro-LED 14G mounted on the mount 51tg may have its upper surface located above the upper end of the light shield 25. This structure reduces the likelihood of side emission light from the micro-LED 14G being absorbed and partially reflected by the light shield 25.

Without the light shield 25, the side wiring 30 is likely to be an uppermost end in a portion near the edge 1t of the substrate 1. Thus, the height from the first surface 1a to the upper surface of the side wiring 30 may be less than or equal to the height from the first surface 1a to the upper surface of the micro-LED 14G mounted on the mount 51tg. In some embodiments, the height from the first surface 1a to the upper surface of the side wiring 30 may be less than or equal to the height from the first surface 1a to the lower surface of the micro-LED 14G mounted on the mount 51tg.

The micro-LED 14G mounted on the mount 51tg may have its overall side surface located above the upper end of the light shield 25. This structure further reduces the likelihood of side emission light from the micro-LED 14G being absorbed and partially reflected by the light shield 25. In this case, the difference between the lower end of the side surface of the micro-LED 14G mounted on the mount 51tg and the upper end of the light shield 25 may be 0 to 100 μm inclusive.

The light shield 25 covers the frame 1g for being inconspicuous and protects the side wiring 30 on the side surface 1s of the substrate 1. The light shield 25 may thus extend beyond the side surface 1s of the substrate 1. The display device according to the present embodiment may include multiple substrates 1 each including multiple micro-LEDs 14. The multiple substrates 1 may be arranged in a grid on the same plane. The substrates 1 may be connected (tiled) together with their side surfaces bonded with, for example, an adhesive. The display device can thus be a composite and large multi-display with joints between the substrates 1 being less conspicuous under the light shield 25.

The light shield 25 may have a color that efficiently absorbs and blocks visible light, for example, black, blackish brown, dark brown, dark blue, or dark purple. The light shield 25 may be a light shielding film including a transparent resin layer containing, for example, dark-colored pigments, dyes, ceramic particles, metal particles, alloy particles, or resin particles, a sticker bonded with an adhesive or a bond, or a frame of, for example, plastic bonded with an adhesive or a bond. The light shield 25 absorbs and blocks most visible light.

The above light shielding film as the light shield 25 is formed by placing an uncured resin paste containing, for example, a dark-colored pigment or dye on the frame 1g on the substrate 1 by applying and printing with a method such as coating, printing using a mask, or roller printing, and then curing the resin paste with a method such as thermal curing, photocuring using, for example, ultraviolet ray irradiation, or photothermal curing.

The light shield 25 has substantially the same width as the frame 1g, which is about 20 to 110 μm.

As shown in FIG. 2, the light emitter boards LS1 and LS2 according to the present embodiment include multiple mounts 51tg, 51tr, and 51tb on the substrate 1. The mount 51tg receives the micro-LED 14G. The mount 51tr receives the micro-LED 14R. The mount 51tb receives the micro-LED 14B. The micro-LEDs 14G, 14R, and 14B may have different emission colors. In this case, the display device can perform high-quality full-color image display.

The pixel unit 15b including the multiple micro-LEDs 14R, 14G, and 14B having different emission colors serves as a display unit. For example, a color display device includes pixel units each including a red-light emissive micro-LED 14R, a green-light emissive micro-LED 14G, and a blue-light emissive micro-LED 14B to enable display of color tones.

In some embodiments, the micro-LEDs 14R, 14G, and 14B included in one pixel unit 15b may not be aligned on a single straight line as viewed in plan. In this case, the pixel unit 15b is smaller as viewed in plan, and may be compact and square as viewed in plan. The display device or other devices thus include pixels with higher density and less irregularities, enabling high-quality image display.

In some embodiments, the micro-LEDs 14R, 14G, and 14B included in one pixel unit 15b may be aligned on a single straight line as viewed in plan. This facilitates arrangement of a first group of multiple micro-LEDs 14R, 14G, and 14B for primary driving and a second group of multiple micro-LEDs 14R, 14G, and 14B for redundant driving in one pixel unit 15b.

The pixel unit 15b may include emission controllers 22r, 22g, and 22b including a TFT, serving as a switch or a control element for controlling the emission or non-emission state and the light intensity of the micro-LEDs 14R, 14G, and 14B. The emission controllers 22r, 22g, and 22b may be located below the micro-LEDs 14R, 14G, and 14B with an insulating layer between them. In this case, the pixel unit 15b is smaller as viewed in plan, and may be compact and square as viewed in plan. The display device or other devices thus include pixels with higher density and less irregularities, enabling high-quality image display.

A display device according to one or more embodiments includes any of the light emitter boards LS1 or LS2 according to the embodiments with the above structure. The substrate 1 has the first surface 1a (shown in FIG. 5) on which the micro-LEDs 14 are mountable, a second surface 1b (shown in FIG. 6) opposite to the first surface 1a, and side surfaces is (shown in FIGS. 5 and 6). The light emitter boards LS1 and LS2 include the side wiring 30 (shown in FIGS. 5 and 6) on the side surfaces 1s, and the driver 6 on the second surface 1b. The micro-LEDs 14 are connected to the driver 6 with the side wiring 30. This structure reduces the likelihood that the luminance of the micro-LEDs 14 decreases and the contrast in a displayed image decreases. This structure also reduces the likelihood that the bonding strength of the micro-LEDs 14 to the mounts decreases. The display device can thus have a long service life.

The driver 6 may include driving elements such as ICs and LSI circuits mounted by COG or chip on film (COF), or may be a circuit board on which driving elements are mounted. The driver 6 may also be a thin film circuit including, for example, a TFT that includes a semiconductor layer including low temperature polycrystalline silicon (LTPS) formed directly on the second surface 1b of the substrate 1, which may be a glass substrate, with a thin film formation method such as chemical vapor deposition (CVD).

The side wiring 30 may be formed from a conductive paste including conductive particles such as Ag, Cu, Al, and stainless steel, an uncured resin component, an alcohol solvent, and water. The conductive paste may be cured by heating, photocuring using ultraviolet ray irradiation, or a combination of heating and photocuring. The side wiring 30 may also be formed by a thin film formation method such as plating, vapor deposition, and CVD. The substrate 1 may have grooves on the side surfaces 1s to receive the side wiring 30. This allows the conductive paste to be easily received in the grooves or in intended portions on the side surfaces 1s.

The display device according to the present embodiment may form a light-emitting device. The light-emitting device can be used as, for example, a printer head for an image formation device and other devices, an illumination device, a signboard, a notice board, and a traffic light device.

The display device according to one or more embodiments of the present disclosure is not limited to the above embodiments and may include alterations and improvements as appropriate. For example, the substrate 1 may be a transparent glass substrate, but may be opaque. The substrate 1 being opaque may be a colored glass substrate, a frosted glass substrate, a plastic substrate, a ceramic substrate, a metal substrate, or a composite substrate including a laminate of at least any two of these substrates. The substrate 1 being a metal substrate or a composite substrate including a metal substrate has higher thermal conductivity, and thus has higher heat dissipation.

The present disclosure may be implemented in the following forms.

Alight emitter board according to one or more embodiments of the present disclosure may include a light emitter mounted on the mount with its overall side surface located above the upper surface of the second insulating layer.

In the light emitter board according to one or more embodiments of the present disclosure, the second insulating layer may include a dark-colored light shield layer.

In the light emitter board according to one or more embodiments of the present disclosure, the opening portion may gradually enlarge from the lower end to the upper end.

The light emitter board according to one or more embodiments of the present disclosure may include a dark-colored light shield covering the side surface of the substrate. The upper surface of the light emitter may be located above the upper end of the light shield.

The light emitter board according to one or more embodiments of the present disclosure may include multiple mounts on the substrate each receiving the light emitter. The light emitters may have different emission colors.

In the light emitter board according to one or more embodiments of the present disclosure, the single opening portion may receive the multiple mounts.

In the light emitter board according to one or more embodiments of the present disclosure, the opening portion may have a light-reflective surface. In this case, the surface of the opening portion may include a light-reflective layer formed from, for example, aluminum or silver.

In the light emitter board according to one or more embodiments of the present disclosure, the opening portion may have a shape similar to the shape of the light emitter in a plan view.

In the light emitter board according to one or more embodiments of the present disclosure, the opening portion may have a shape with multiple outwardly expanding curves joined to one another as viewed in plan. In this case, the opening portion may have, for example, a petal shape in a plan view.

In the light emitter board according to one or more embodiments of the present disclosure, the light emitter may be rectangular in a plan view, and the curves of the opening portion may correspond to the sides of the light emitter.

In the light emitter board according to one or more embodiments of the present disclosure, the protrusion may have a light-reflective mount surface receiving the light emitter. In this case, the mount surface may include a light-reflective layer formed from, for example, aluminum or silver.

In the light emitter board according to one or more embodiments of the present disclosure, the protrusion may have a mount surface receiving the at least one light emitter, the mount surface may be larger than the light emitter in a plan view.

In the light emitter board according to one or more embodiments of the present disclosure, the protrusion may be integral with the first insulating layer.

In the light emitter board according to one or more embodiments of the present disclosure, the light emitter mounted on the mount may have its overall side surface located above the upper surface of the second insulating layer. This structure further reduces the likelihood of side emission light from the light emitter being absorbed and partially reflected by the second insulating layer. The light emitter is more reliably pressed onto the mount from above for bonding.

In the light emitter board according to one or more embodiments of the present disclosure, the second insulating layer may include a dark-colored light shield layer. This structure further reduces the likelihood of side emission light from the light emitter being partially reflected by the second insulating layer. This reduces the likelihood that the contrast in a displayed image decreases.

In the light emitter board according to one or more embodiments of the present disclosure, the opening portion may gradually enlarge from the lower end to the upper end. In this case, the opening portion has a bowl-shaped reflective structure. When the side emission light from the light emitter is partially reflected by the inner surface of the opening portion, the reflected light mostly travels upward. This reduces the likelihood that the luminance of the light emitter decreases and the contrast in a displayed image decreases.

The light emitter board according to one or more embodiments of the present disclosure includes a dark-colored light shield covering the side surface of the substrate. The upper surface of the light emitter may be located above the upper end of the light shield. This structure reduces the likelihood of side emission light from the light emitter being absorbed and partially reflected by the light shield.

The light emitter board according to one or more embodiments of the present disclosure includes multiple mounts on the substrate. The multiple mounts may receive the respective light emitters having different emission colors. In this case, the display device can perform high-quality full-color image display.

In the light emitter board according to one or more embodiments of the present disclosure, the single opening portion may receive the multiple mounts. This allows light emitted from the multiple light emitters to easily mix together, enabling higher-quality full-color image display.

In the light emitter board according to one or more embodiments of the present disclosure, the opening portion may have a light-reflective surface from which side emission light from the light emitter is efficiently reflected, thus improving the luminance.

In the light emitter board according to one or more embodiments of the present disclosure, the opening portion may have a shape similar to the shape of the light emitter in a plan view. This causes side emission light from the light emitter to be more efficiently reflected from the surface of the opening portion, thus further improving the luminance.

In the light emitter board according to one or more embodiments of the present disclosure, the opening portion may have a shape with multiple outwardly expanding curves joined to one another, such as a petal shape, in a plan view. This causes side emission light from the light emitter to be efficiently reflected at the curves, thus further improving the luminance.

In the light emitter board according to one or more embodiments of the present disclosure, the light emitter may be rectangular in a plan view, and the curves of the opening portion may correspond to the sides of the light emitter. This causes side emission light from the light emitter to be more efficiently reflected at the curves, thus further improving the luminance.

In the light emitter board according to one or more embodiments of the present disclosure, the protrusion may have a light-reflective mount surface receiving the light emitter. The mount surface effectively reflects light emitted downward from the light emitter, thus improving the luminance.

In the light emitter board according to one or more embodiments of the present disclosure, the protrusion may have a mount surface receiving the at least one light emitter, the mount surface may be larger than the light emitter in a plan view. This allows reliable electrical connection of the light emitter on the mount surface and reliable arrangement of the light emitter on the mount surface. The mount surface that is light-reflective effectively reflects the light emitted downward from the light emitter, thus improving the luminance.

In the light emitter board according to one or more aspects of the present disclosure, the protrusion may be integral with the first insulating layer. In this case, the protrusion can be formed with accurate height with a processing method such as photolithography.

In the display device, when the height from the first surface to the upper surface of the side wiring is less than or equal to the height from the first surface to the upper surface of the light emitter mounted on the mount, the upper surface of the light shield 25 is unlikely to be located above the upper surface of the light emitter 14.

### INDUSTRIAL APPLICABILITY

The display device according to one or more embodiments of the present disclosure can be a display device such as an LED display device and an organic EL display device. The display device according to one or more embodiments of the present disclosure can be used in various electronic devices. Such electronic devices include composite and large display devices (multi-displays), automobile route guidance systems (car navigation systems), ship route guidance systems, aircraft route guidance systems, smartphones, mobile phones, tablets, personal digital assistants (PDAs), video cameras, digital still cameras, electronic organizers, electronic books, electronic dictionaries, personal computers, copiers, terminals for game devices, television sets, product display tags, price display tags, programmable display devices for industrial use, car audio systems, digital audio players, facsimile machines, printers, automatic teller machines (ATMs), vending machines, head-mounted displays (HMDs), digital display watches, and smartwatches.

The present invention may be embodied in various forms without departing from the spirit or the main features of the present invention. The embodiments described above are thus merely illustrative in all respects. The scope of the present invention is defined not by the description given above but by the claims. Any modifications and alterations contained in the claims fall within the scope of the present invention.

### REFERENCE SIGNS LIST

1 substrate
1g frame
1s side surface
1t edge of substrate
2 scanning signal line
2p electrode pad
3 emission control signal line
14, 14B, 14G, 14R light emitter (micro-LED)
14L, 14BL, 14GL, 14RL light emitting unit
25 light shield
30 side wiring
51 resin insulating layer (first insulating layer)
51t end face of resin insulating layer
51tb, 51tg, 51tr mount
54a positive electrode
54b negative electrode
56 light shield layer (second insulating layer)
56k opening portion
LS1, LS2 light emitter board
Tog protrusion

1. A light emitter board comprising:
a substrate;
a first insulating layer on the substrate;
a second insulating layer on the first insulating layer;
an opening portion in the second insulating layer;
at least one mount on a part of the first insulating layer exposed in the opening portion, the at least one mount receiving at least one light emitter; and
the at least one light emitter on the at least one mount,
wherein the at least one mount includes a protrusion on the part of the first insulating layer, and
the at least one light emitter has an upper surface located above an upper surface of the second insulating layer.

2. The light emitter board according to claim 1, wherein
the at least one light emitter has an overall side surface located above the upper surface of the second insulating layer.

3. The light emitter board according to claim 1, wherein
the second insulating layer includes a dark-colored light shield layer.

4. The light emitter board according to claim 1, wherein
the opening portion gradually enlarges from a lower end to an upper end of the opening portion.

5. The light emitter board according to claim 1, further comprising:
a dark-colored light shield covering a side surface of the substrate,
wherein the upper surface of the at least one light emitter is located above an upper end of the light shield.

6. The light emitter board according to claim 1, wherein
the at least one mount includes a plurality of mounts on the substrate,
the at least one light emitter includes a plurality of light emitters, and each of the plurality of light emitters is on a corresponding mount of the plurality of mounts and has a corresponding emission color different from an emission color of another light emitter of the plurality of light emitters.

7. The light emitter board according to claim 6, wherein
the opening portion is a single opening portion in which the plurality of mounts are located.

8. The light emitter board according to claim 1, wherein
the opening portion has a light-reflective surface.

9. The light emitter board according to claim 1, wherein
the opening portion has a shape similar to a shape of the at least one light emitter in a plan view.

10. The light emitter board according to claim 1, wherein
the opening portion has a shape including a plurality of outwardly expanding curves joined to one another in a plan view.

11. The light emitter board according to claim 10, wherein
the at least one light emitter is rectangular in a plan view, and
the plurality of outwardly expanding curves of the opening portion correspond to sides of the at least one light emitter.

12. The light emitter board according to claim 1, wherein
the protrusion has a light-reflective mount surface receiving the at least one light emitter.

13. The light emitter board according to claim 1, wherein
the protrusion has a mount surface receiving the at least one light emitter, the mount surface being larger than the at least one light emitter in a plan view.

14. The light emitter board according to claim 1, wherein
the protrusion is integral with the first insulating layer.

15. A display device, comprising:
the light emitter board according to claim 1,
wherein the substrate has a first surface receiving the at least one light emitter, a second surface opposite to the first surface, and side surfaces,
the light emitter board includes side wiring on the side surfaces and a driver on the second surface, and
the at least one light emitter is connected to the driver with the side wiring.

16. The display device according to claim 15, wherein
a height from the first surface to an upper surface of the side wiring is less than or equal to a height from the first surface to the upper surface of the at least one light emitter on the at least one mount.
